(19) United States
(12) Patent Application Publication
(10) Pub. No.: US 2024/0113496 A1
(43) Pub. Date: Apr. 4, 2024

(54) Compact Optical System For A VCSEL Based Laser Aim Pattern Generator

(71) Applicant: ZEBRA TECHNOLOGIES CORPORATION, Lincolnshire, IL (US)

(72) Inventors: Matthew D. Blasczak, Shirley, NY (US); Chinh Tan, East Setauket, NY (US)

(21) Appl. No.: 17/956,383

(22) Filed: Sep. 29, 2022

(51) Int. Cl. H01S 5/02253; H01S 5/0232; H01S 5/183; H05K 1/18

(52) U.S. Cl. CPC H01S 5/02253; H01S 5/0232; H01S 5/18361; H05K 1/181; H05K 2201/10121

(57) ABSTRACT

An optical pattern generating system for providing an aiming pattern in a field of view (FOV). The optical pattern generating system includes a light source configured to provide light along an optical axis, the light source including a vertical-cavity surface-emitting laser. The system further includes an optical substrate disposed along the optical axis configured to receive the light from the light source, the optical substrate having a first surface having a first flat optical element thereon, the first flat optical element being an element that collimates the light, a second surface having a second flat optical element thereon, the second flat optical element configured to diffract the light to form an optical pattern, and a thickness defined by the distance between the first surface and second surface.

### BACKGROUND OF THE INVENTION

Imaging devices generally capture images within a given field of view (FOV). It is often required that that scanning devices capture images at various distances and at various fields of view to effectively decode information in an image for use in machine vision applications. Additionally, the demand for portable sensors is increasing which requires the use of smaller sensors and smaller illumination systems. Typical barcode readers, such as handheld barcode readers, point of sale scanners, and direct part marking scanners, require proper illumination of targets within one or more fields of view (FsOV) to obtain high quality, low-blur images to decode barcodes in the images. The illumination of an object or barcode is essential for decoding of barcodes in captured images and various factors such as time of day, direction of illumination, illumination intensity, and light type or light source type all effect how effective a system may be in decoding barcodes. Additionally, the type of barcode, the reflectivity of a target, and the distance or size of a target are also all important factors in decoding barcodes in captured images. Therefore, the position of an object in the illumination is essential for successfully performing scanning and decoding of indicia for many applications.

Imaging barcode readers require illumination sources to illuminate a target. A user or operator of a scanner must either position a target object relative to a field of view of a scanner, or position the scanner, such as a handheld scanner, at a position to image or scan a target. This requires the target to be within a field of view of the scanner at an appropriate distance from the scanner. If the target is too far away from the scanner, the image may not be properly illuminated or have a quality capable of decoding a barcode imaged therein. Some scanners rely on a user to discern the field of view of the scanner, while others may employ a mechanism to provide guidance to a user such as a physical window to place an object on or in front of. Additionally, the field of view of a scanner may change at different distances from the scanner, resulting in the ability to scan a target at one distance from the scanner, while not being able to scan the same target at other distances closer or further from the scanner. Many scanner systems do not provide adequate guidance to a user resulting in long scanning times and scanning errors due to objects being too close, too far, outside of a field of view of the scanner, or partially in the view of view of the scanner. As such, it could be beneficial for a scanning system to improve scanning speed times by providing a user with guidance to the field of view of a scanning system at various distances from the scanner. Additional optical elements for providing guidance to a user require increased size, power, and cost of scanning devices, which is further exacerbated for portable systems that may need to be handheld and powered by batteries and portable resources.

Accordingly, there is a need for improved systems, methods, and devices which address these issues.

### SUMMARY

In an embodiment, the present invention is an optical pattern generating system for providing an aiming pattern to a field of view. The optical pattern generating system includes a light source configured to provide light along an optical axis, the light source including a vertical-cavity surface-emitting laser; and an optical substrate disposed along the optical axis configured to receive the light from the light source, the optical substrate having (i) a first surface having a first flat optical element thereon, the first flat optical element being an element that collimates the light, (ii) a second surface having a second flat optical element thereon, the second flat optical element configured to diffract the light to form an optical pattern, and (iii) a thickness defined by the distance between the first surface and second surface.

In a variation of the current embodiment, the first optical element comprises a metalens. In a variation of the current embodiment, the second flat optical element comprises a flat diffractive optical element. In any variations of the current embodiment, the diffractive optical element diffracts the light to form either an optical aiming pattern or a point cloud pattern.

In a variation of the current embodiment, the optical pattern generating system further includes a photodiode disposed to detect a portion of the light and configured to generate a signal indicative of the detected portion of the light. In yet a further variation of the current embodiment, the first surface further comprises a reflective element, the reflective element configured to reflect the portion of the radiation from the first surface toward the photodiode. In another variation of the current embodiment, the reflective element includes a mirror.

In more variations of the current embodiment, the optical pattern generating system further comprises a printed circuit board having the light source disposed thereon, the light source being electrically coupled to the [printed circuit board. In a variation of the current embodiment, the light source is a surface mount device and the light source is surface mounted to the printed circuit board.

In another embodiment, the present invention is an optical pattern generating system including a housing structure having (i) one or more side walls, (ii) a bottom wall, and (iii) a front aperture disposed along an optical axis, the front aperture configured to allow light to propagate through the front aperture. The system further includes a printed circuit board disposed in the housing structure and supported in position by the housing structure; a light source physically and electrically coupled to the printed circuit board, the light source being a vertical-cavity surface-emitting laser configured to provide light along the optical axis; an optical substrate disposed in the housing, the optical substrate having (i) a first surface toward the light source, the first surface having a first flat optical element thereon the first flat optical element configured to collimate the light, (ii) a second surface opposite the first surface, the second surface having a second flat optical element thereon the second flat optical element configured to diffract the light into an optical pattern, and (ii) a thickness defined by the distance from the first surface to the second surface.

In a variation of the current embodiment, the system of claim further includes a baffle disposed on the front aperture configure to block light from exiting a portion of the front aperture. In more variations of the current embodiment, the housing has a width of less than 3 millimeters between opposite walls of the one or more side walls, and a height of less than 3 millimeters between the bottom wall and the front aperture.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is a schematic side elevation view of an imaging device having a compact aiming system in accordance with some embodiments.

FIG. 2 is a schematic top-view of an imaging scanning station having an autofocus system, an adaptive illumination system, and compact aiming system in accordance with some embodiments.

FIG. 3 illustrates a block connection diagram of system including an imaging reader in accordance with the teachings of this disclosure.

FIG. 4 is a cross-sectional side view of an embodiment of an optical assembly of a compact aiming system.

FIG. 5 is a cross-sectional side view block diagram of optical elements of the optical assembly of FIG. 4.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

Portable high-performance optical imaging systems for machine vision employ small imaging sensors to maintain small form factors. For example a typical machine vision imaging sensor has an imaging sensor rectangular area of around 3 by 3 millimeters with sensor pixels areas of approximately 3 microns. Some high-performance compact machine vision systems require wide angle fields of view (FOVs) (e.g., greater than 40 degrees) in addition to small form factor imaging sensors. Barcode readers often require wide imaging FOVs for efficiently reading barcodes at short distances, while requiring narrower FOVs to efficiently read barcodes at further distances. The change in the FOV of a barcode reader changes the pixels per module (PPM) that is able to be imaged by the barcode reader, and therefore, changes the efficiency of barcode imaging and reading. Typically, a barcode reader requires a minimum PPM to properly read a barcode. Due to these stringent requirements, the illumination of an object is very important for capturing images for decoding efficiently. As such, the position of an object in a FOV is crucial for performing scanning of indicia and machine vision processes.

As described, efficient operation of a scanner requires that a target objects for scanning be in a field of view of the scanner. As such, scanner systems may include means for indicating a field of view to a user such as translucent tables or windows indicative of the field of view. While a window may assist with communicating a field of view for a stationary system, handheld scanners or portable scanners may benefit from further measure to indicate a field of view of the scanner. Additionally, a user may position items to be scanned at various distances from the scanner which may result in the target being outside of the field of view, or partially within the field of view. The disclosed system provides a spatially compact solution that provides visual guidance indicative of a field of view of a scanner. Further, the system utilizes a vertical-cavity surface-emitting laser (VCSEL) and planar optical elements that allow for reduce the overall size of the system allowing for implementation in compact and portable scanners. The disclosed system may be employed in autofocus imaging systems, auto-zoom imaging systems, imaging systems that employ multiple cameras having multiple fields of view, stationary point of sale systems, portable scanners, machine vision systems, and other imaging and scanning systems and apparatuses.

To implement a compact barcode reader, an internal aiming system may be required. The current disclosure describes an aiming system that utilizes a VCSEL as the light source and flat optical elements to generate an aiming pattern indicative of a FOV of a scanner. The scanner may be a point of sale system, portable barcode decoder, machine vision system, or another imaging system. The VCSEL and flat optics are package inside of a housing to form the aiming system. The flat optics includes a flat substrate with a metalens on one surface of the substrate, and diffractive optical element (DOE) on an opposing surface of the substrate. A feature on the substrate further reflects some light from the VCSEL to a photodiode to provide a feedback signal to monitor and control the VCSEL radiation intensity output. The use of flat optical elements and a VCSEL reduces the overall size of the aiming system, and the VCSEL has a lower threshold current than other laser sources (e.g., edge emitting lasers) allowing for reduced power consumption (e.g., reduced by approximately 70 mW as compared to typical edge emitting lasers).

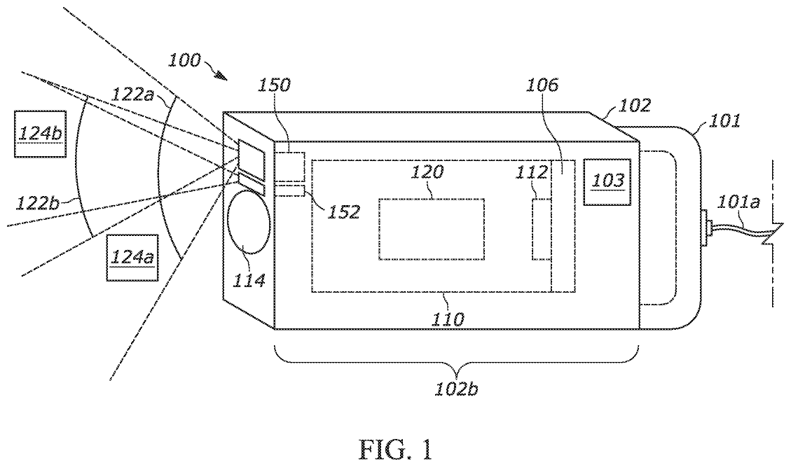

A first embodiment of an imaging device, that may include a compact aiming pattern generator as described herein, is shown schematically in FIGS. 1-3. The imaging device 100 includes a housing 102, an illumination system 150, and aiming system 152, and an imaging system 110 at least partially disposed within the housing 102 that includes an imaging camera assembly. Specifically, the imaging system 110 includes an image sensor 112 and a lens assembly 120. The device 100 may be adapted to be inserted into a docking station 101 which, in some examples, may include an AC power source 101a to provide power for the device 100. The device 100 may further include an onboard power supply 103, such as a battery and a printed circuit board 106 that may accommodate a memory and a controller that controls operation of the imaging system 110. In embodiments, the device 100 may include a trigger (not shown in the illustration) is used to activate the imaging system 110 to capture an image. The device 100 may include any number of additional components such as decoding systems, processors, and/or circuitry coupled to the circuit board 106 to assist in operation of the device 100.

The housing 102 includes a forward or reading head portion 102b which supports the imaging system 110 within an interior region of the housing 102. The imaging system 110 may, but does not have to be, modular as it may be removed or inserted as a unit into the devices, allowing the ready substitution of illumination systems 150 and/or imaging systems 110 having different illumination and/or imaging characteristics (e.g., illumination systems having different illumination sources, lenses, illumination filters, illumination FOVs and ranges of FOVs, camera assemblies having different focal distances, working ranges, and imaging FOVs) for use in different devices and systems. In some examples, the field of view may be static.

The image sensor 112 may have a plurality of photosensitive elements forming a substantially flat surface and may be fixedly mounted relative to the housing 102 using any number of components and/or approaches. The image sensor 112 further has a defined central imaging axis, A, that is normal to the substantially flat surface. In some embodiments, the imaging axis A is coaxial with a central axis of the lens assembly 120. The lens assembly 120 may also be fixedly mounted relative to the housing 102 using any number of components and/or approaches. In the illustrated embodiment, the lens assembly 120 is positioned between a front aperture 114 and the image sensor 112. The front aperture 114 blocks light from objects outside of the field of view which reduces imaging problems due to stray light from objects other than the target object. Additionally, the front aperture 114 in conjunction with a one or more lenses allows for the image to form correctly on the imaging sensor 112.

The housing 102 includes an illumination system 150 configured to illuminate a target object of interest for imaging of the target. The target may be a 1D barcode, 2D barcode, QR code, UPC code, or another indicia indicative of the object of interest such as alphanumeric characters or other indicia. The illumination system 150 may be a dual FOV illumination system as described further herein. The illumination system 150 may adaptively provide a wide-angle illumination FOV 122a to enable wide-angle imagine of a close target 124a, or provide a narrow-angle illumination FOV 122b to for imagine of a far-away target 124b. In other implementations, the illumination system 150 may provide illumination to a single FOV, or multiple FOVs of the imaging system 110.

The housing 102 further includes an aiming system 152 disposed at least partially in the housing 102. The aiming system 152 provides an aiming target pattern in the one or more FOVs of the imaging system 110 to indicate, to a user, a scanning position to place an object within the FOV of the imaging device 100. The aiming pattern may be indicative of a center position of the one or more FOVs. The aiming pattern may indicate a height, width, or other position r dimension of one or more OFVs of the imaging system 110. The aiming pattern may include a dot, lines, dotted lines, dot-dash lines, shapes such as circles, rectangles, squares, etc. for indicating a position for placing an object to be imaged or scanned. For example, the aiming pattern may be a horizontal line indicative of a total width of a FOV, a dot indicative of a center of a FOV, or a rectangle to indicate a region of a FOV to place an object, among other examples. The aiming system 152 includes a source of light, or radiation, and aiming optics to collimate and/or focus the light, and to generate the aiming pattern. The aiming system 152 may be modular or include modular components to be able to change the aiming patter, light source, or to be used in multiple models and types of imaging devices 100.

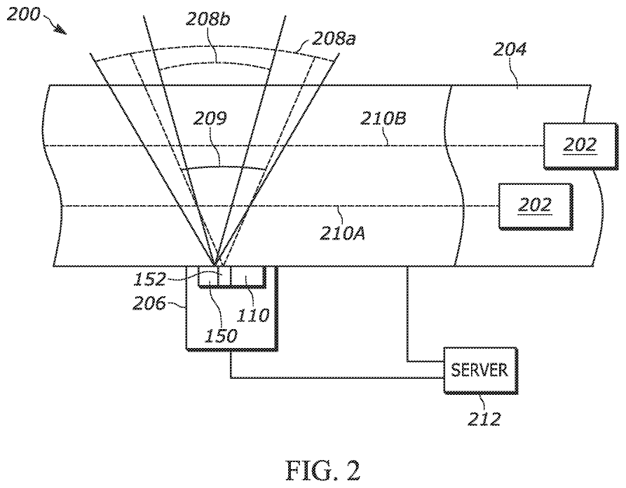

FIG. 2 illustrates an embodiment of a scanning station 200 that includes a compact aiming system 152. Goods 102 are moved across or along a scanning surface 204, are illuminated by a dual FOV illumination source 150, and imaged by an imaging system 110, of an imaging reader 206 to identify the goods 202. The aiming system 152 provides an aiming pattern in an aiming region 209 in the FOVs of the imaging system 110. Using the aiming pattern, a user may determine that the good 102 are adequately in the FOVs of the imaging system 110, or, using the aiming pattern, the user may trouble shoot or adjust the system or the goods 102 to ensure the goods are properly imaged and scanned. In some embodiments, the scanning station 200 is a point-of-sale (POS) station, which may have a computer system and an interface, not shown, for optically scanning goods and identifying the goods and characteristics of the goods for affecting a transaction. In some embodiments, the scanning station is part of an inventory delivery system, where goods are conveyed by the scanning surface or across the scanning surface to monitor and control delivery of the goods, for example, shipping goods from a facility or receiving shipped goods to a facility.

The scanning surface 204 may be a stationary surface, such that the goods 202 are manually moved relative to the surface 204. In embodiments, the scanning surface 204 may move the goods 202 or be moved by another automated means. In other embodiments, the scanning surface 204 may be a moving surface, such as by a conveyor system such as a conveyer belt, pneumatic conveyer, wheel conveyer, roller conveyer, chain conveyer, flat conveyer, vertical conveyer, trolley conveyer, or another conveyer. In any case, the goods 202 may be moved continuously relative to the imaging reader 206, such that the goods 202 are constantly moving through a current working (or scanning) range of the station 200. For example, the station may have a wide-angle working range 208a and a narrow FOV 208b depending on the distance of the good 202, an illumination FOV of the dual FOV illumination system 150, and/or an FOV of the imaging system 110. The aiming pattern may be configured to provide a single aiming pattern to both working ranges 208a and 208b, of the aiming system 152 may provide one aiming pattern to the wide-angle working range 208a, and another pattern to the narrow FOV 208b. For example, the aiming system 152 may provide a line showing a width of the wide-angle working range 208a, and provide a dot, or circle showing the center of the narrow FOV 208b. Additionally, the aiming source 152 may provide different colors of aiming patterns to each working range 208a and 208b. In some examples, the goods 202 move in a discretized manner, where, at least part of the time the goods 202 are maintained fixed on the surface 204 relative to the imaging reader 206 for a period of time, sufficient to allow one or more images to be captured of the goods 202.

The goods 202 may move along different substantially linear paths 210A, 210B, etc. each path traversing the working ranges 208a and 208b, and associated aiming patters, but at a different distance from the imaging reader 206. The dual FOV illumination system 150 may provide illumination according to one or more illumination FOVs depending on the distance of the goods 202 from the imaging reader 206. For example, the imaging system 110 may determine an imaging focal distance of the good 202 and the dual illumination system 150 may provide illumination having a FOV depending on the imaging focal distance. In embodiments, a controller may control the dual illumination system 150 to control the FOV of the dual illumination system 150. The paths 210A, 210B are for illustration purposes, as the goods 202 may traverse across the surface 204 at any distance from the imaging reader 206, and, accordingly, the dual FOV illumination system may provide one or more illumination FOVs for imaging the goods depending on the distance of the goods 202 from the imaging reader 206. While described as a dual FOV system, the device 100 may include a variable FOV imaging system 110 that uses tunable optical elements for capturing images in a range of FOVs. The systems are described herein as having two FOVs for clarity and simplicity, but it should be understood that the imaging system 110, illumination system 150, and aiming system 152 may provide scanning functionality over a larger number of FOVs.

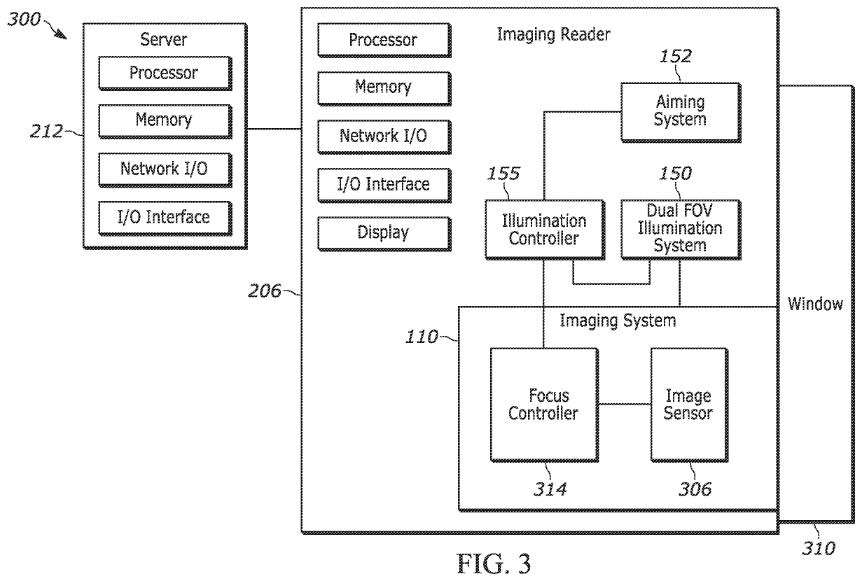

FIG. 3 illustrates a block connection diagram of system 300 including an imaging reader 206. While in reference herein to the imaging reader 206 of FIG. 2, the system 300 may be implemented with the imaging device 100 of FIG. 1. In FIG. 3 the imaging reader 206 may have one or more processors and one or more memories storing computer executable instructions to perform operations associated with the systems and methods as described herein. The imaging reader 206 includes a network input/output (I/O) interface for connecting the reader to the server 212, an inventory management system (not shown), and other imaging readers. These devices may be connected via any suitable communication means, including wired and/or wireless connectivity components that implement one or more communication protocol standards like, for example, TCP/IP, WiFi (802.11b), Bluetooth, Ethernet, or any other suitable communication protocols or standards. The imaging reader 106 further includes a display for providing information such as visual indicators, instructions, data, and images to a user.

In some embodiments, the server 212 (and/or other connected devices) may be located in the same scanning station 200. In other embodiments, server 212 (and/or other connected devices) may be located at a remote location, such as on a cloud-platform or other remote location. In still other embodiments, server 212 (and/or other connected devices) may be formed of a combination of local and cloud-based computers.

Server 212 is configured to execute computer instructions to perform operations associated with the systems and methods as described herein. The server 212 may implement enterprise service software that may include, for example, RESTful (representational state transfer) API services, message queuing service, and event services that may be provided by various platforms or specifications, such as the J2EE specification implemented by any one of the Oracle WebLogic Server platform, the JBoss platform, or the IBM WebSphere platform, etc. Other technologies or platforms, such as Ruby on Rails, Microsoft .NET, or similar may also be used.

In the illustrated example, the imaging reader 206 includes a dual FOV illumination system 150, which may include a visible light source (e.g., a light emitting diode (LED) emitting at 640 nm) or an infrared light source (e.g., emitting at or about 700 nm, 850 nm, or 940 nm, for example), with the dual FOV illumination system 150 capable of generating an illumination beam that illuminates the working range 208a or 208b for imaging over an entire working distance of that working range 208a or 208b. That is, the dual FOV illumination system 150 is configured to illuminate over at least each of the entire working ranges 208a and 208b. In embodiments, the dual FOV illumination system 150 may be capable of illuminating a plurality of working ranges with each having a corresponding FOV and working distance from the imaging reader 206. The illumination intensity of the dual FOV illumination system 150 and the sensitivity of an imaging reader can determine the further and closest distances (defining the distance of the working range, also termed the scanning range), and the working ranges in respect to illumination FOV, over which a good can be scanned, and a barcode on the good can be decoded.

The dual FOV illumination system 150 may be controlled by a processor and may be a continuous light source, an intermittent light source, or a signal-controlled light source, such as a light source trigged by an object detection system coupled (or formed as part of though not shown) to the imaging reader 206. The dual FOV illumination system may include a light source such as a laser diode, an LED, a black body radiation source, an infrared light source, a near-infrared light source, an ultraviolet light source, a visible light source, an omnidirectional illumination source, or another illumination source. Additionally, the dual FOV illumination system 150 may include optics for dispersing, focusing, spreading, and/or filtering optical radiation for illumination of the target object. In embodiments, the dual FOV illumination system 150 may be housed inside of the housing 102 of FIG. 1 or may attach to the external surfaces of the housing 102. In embodiments, the imaging system 110 may be housed in the imaging reader 206 of FIG. 3 or may attach to the external surface of the imaging reader 206. In embodiments, the dual FOV illumination system 150 may be a separate device or component from the housing 102 and/or imaging reader 106, with the dual FOV illumination system 150 configured to illuminate the target object for capturing an image by the imagine device 100 or the imaging reader 106.

The imaging system also includes an aiming system 152 which may include a visible light source (e.g., a light emitting diode (LED) emitting at 640 nm) or an infrared light source (e.g., emitting at or about 700 nm, 850 nm, or 940 nm, for example), with the aiming system 152 capable of generating an aiming target pattern that provides guidance to scanning positions in the working ranges 208a or 208b for imaging an object and indicia in the working ranges 208a or 208b. The dual aiming system 150 may be controlled by a processor and may be a continuous light source, an intermittent light source, or a signal-controlled light source, such as a light source trigged by an object detection system coupled (or formed as part of though not shown) to the imaging reader 206. The aiming system may include a light source such as a laser diode, an LED, a black body radiation source, an infrared light source, a near-infrared light source, an ultraviolet light source, a visible light source, an omnidirectional illumination source, or another illumination source. In embodiments described herein, the aiming system 152 implements a VCSEL laser diode as a light source. Additionally, the aiming system 152 may include optics for dispersing, focusing, spreading, and/or filtering optical radiation for illumination of the target object. For example, the aiming system 152 may employ an optical substrate with a micro-lens array (MLA) on one surface of the substrate, with the MLA configured to collimate the light from the VCSEL. Another surface of the optical substrate may include a DOE that disperses the collimated light to form the aiming target pattern to in the working ranges 208a and 208b In embodiments, the dual FOV illumination system 150 may be housed inside of the housing 102 of FIG. 1 or may attach to the external surfaces of the housing 102. In embodiments, the imaging system 110 may be housed in the imaging reader 206 of FIG. 3 or may attach to the external surface of the imaging reader 206. In embodiments, the dual FOV illumination system 150 may be a separate device or component from the housing 102 and/or imaging reader 106, with the dual FOV illumination system 150 configured to illuminate the target object for capturing an image by the imagine device 100 or the imaging reader 106.

The imaging reader 106 further includes the imaging system 110 having an imaging sensor 306 positioned to capture images of an illuminated target, such as the goods 102 or another object of interest (OOI), within a working range 208a or 208b of the imagine reader 206. In some embodiments, the imaging sensor 306 is formed of one or more CMOS imaging arrays. In some embodiments the imaging sensor may be a charge coupled device or another solid-state device. The imaging sensor 306 may be a one megapixel sensor with pixels of approximately three microns in size. In embodiments, the imaging sensor includes 3 millimeter pixels, having a total of about 2 megapixels, resulting in an overall imaging sensor width and length of 3 microns in each dimension. In embodiments, the imaging sensor 306 may be a variable focus imaging sensor such as an auto-focus camera capable of changing imaging focal planes for imaging objects at different distances from the imaging reader 206.

The imaging reader may include one or more windows 310 for allowing illumination from the dual FOV illumination system 150 and the aiming system 152 to exit the imaging reader 206, and for light from the OOI to reach the image sensor 306. In embodiments, each of the adaptive illumination system 150 and/or the aiming system 152 may be external to the imaging reader 206 and the external illumination and/or aiming system may include a window for transmitting light, or the external illumination and/or aiming system may emit the light into free space without the use of a window. In embodiments, the dual FOV illumination system 150 and/or aiming system 152 may include one or more apertures configured to allow illumination to pass through the apertures to provide illumination or an aiming pattern to the OOI.

A focus controller 314 is coupled to the controls the imaging sensor 306 and any variable focus optics (e.g., a deformable lens, a liquid lens, a translatable lens, a translatable grating, or other variable focus optical elements) to define one or more discrete imaging planes for the imaging sensor 306. In embodiments, the imaging system 110 may include a focusing lens drive, a shift lens drive, a zoom lens drive, an aperture drive, angular velocity drive, voice coil motor drive, and/or other drive units for controlling the focal distance of the imaging system 110, which may further include multiple lens, lens stages, etc. In embodiments, once a focal plane for imaging an OOI is established by the image sensor 306, the focus controller 314, and/or a processor in communication with the image sensor 306 and focus controller 314, information indicative of the focal distance may be provided to the illumination controller 55. The illumination controller 155 may process the information indicative of the focal distance to determine a desired FOV and illumination distance (i.e., illumination intensity output) of the dual FOV illumination system 150. The illumination controller 155 may then control the dual FOV illumination system 150 to cause the dual FOV illumination system 150 to provide illumination according to the determined FOV for an illumination distance. For example, the controller 155 may control the dual FOV illumination system 150 to cause the dual FOV illumination system 150 to provide near-field illumination, or far-field illumination discussed further herein. In some embodiments, the dual FOV illumination system 150 includes a plurality of illumination sources and the dual FOV illumination system 150 may control one or more of the plurality of illumination sources to provide a FOV according to the desired illumination distance. The controller 155 may control the aiming system 152 to provide an aiming pattern along with illumination provided by the dual FOV illumination system 150, or intermittently depending on various operable modes of the imaging reader 206. For example, the controller 155 may control the aiming system 152 to cause the aiming system 152 to not provide the aiming pattern during an object detect mode, or a dormant mode of the imaging reader 206, and the controller 155 may cause the aiming system 152 to provide the aiming pattern during a scanning mode of the reader 206.

In embodiments, the memory may store information regarding the focal distances of OOIs such as the good 202 and the illumination controller 155 may retrieve the information from the memory to determine a desired illumination FOV and illumination intensity, or a plurality of potential illumination FOVs and illumination intensities. The illumination controller 155 may then determine, based on information from the focus controller 314 one of the plurality of illumination FOVS and illumination intensities, and control the dual FOV illumination system 150 to provide illumination at the determined illumination FOV and illumination intensity. Further, the illumination controller may control the dual FOV illumination system 150 to provide illumination according to various FOVs and illumination intensities to determine desired illumination parameters for a given OOI, or to provide the imaging system 110 with various illuminations for capturing a plurality of images on an OOI. A preferred illumination may then be determined by the imaging system 110, or a processor in communications with the imaging system 110, and the illumination controller 155 may be provided with the determined desired illumination. The memory may store information indicative of the aiming pattern and or elements of the aiming system 152. For example, the memory may store information indicative of electrical characteristics of a VCSEL or other aiming light source. The information may be indicative of a current or voltage to provide to the aiming light source to operate the aiming light source.

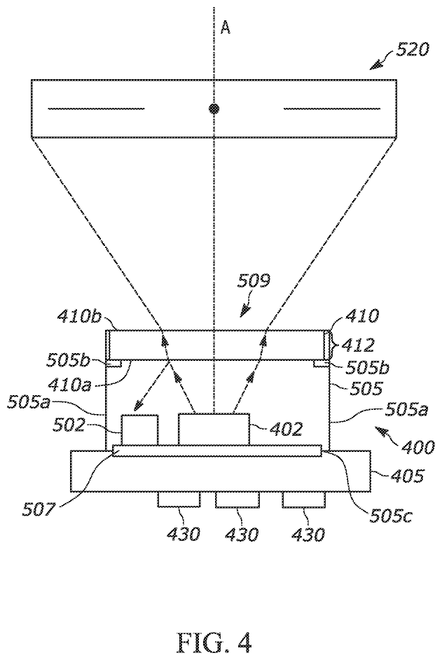

FIG. 4 is a cross-sectional side view of an embodiment of an optical assembly 400 of a compact aiming system. The optical assembly 400 includes an aiming light source 402 disposed to provide light along an optical axis A. In examples the aiming light source 402 may be a laser diode, such as a VCSEL. The light source 402 is surface mounted to a printed circuit board 405 (PCB). Surface mounting the aiming light source 402 allows for additional components 430 to be mounted on the PCB, and electrically coupled to the PCB, on a side of the PCB opposite that of the aiming light source 402. As such, the described optical assembly 400 allows for more efficient use of real estate of the PCB which reduces the overall size of the optical assembly 400 compared to other aiming systems.

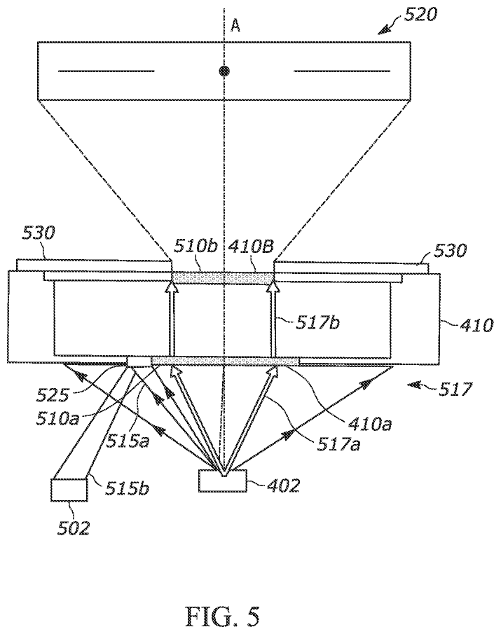

The aiming light source 402 may be physically mounted to the PCB 405 via one or more surface mount solder pads 507. The optical assembly further includes a frame package 505 that contains the aiming light source 402. The frame package 505 further supports a compact flat optical substrate 410 in a position along the optical axis A configured to receive light from the aiming light source 402. The frame package 505 may be made of lead, or another material. The frame package 505 is a housing structure that may contain elements of the optical assembly 400. The frame package 505 includes one or more side walls 505a and a front aperture 509 through which light may pass. The frame package 505 may further include substrate mounts 505b for physically supporting a position of the flat optical substrate 410 along the optical axis A. In examples, the frame package may have an overall width between sidewalls 505a of less than 3 mm, less than 5 mm, or less than 10 mm. The frame package 505 may also have an overall height of less than 3 mm, less than 5 mm, or less than 10 mm between a bottom wall 505c of the frame package 505c and the aperture 509. While illustrated as being physically coupled to the bottom of the frame package 505, in examples, the PCB may be disposed inside of the frame package 505 housing. The frame package 505 may having mount solder pads, wherein the light source 402 is physically and electrically coupled to the lead frame package 505. Further, a photodiode, discussed further with reference to FIG. 5, may also be physically and electrically coupled to the lead frame package 505, and the PCB 405 may be physically and electrically coupled to the lead frame package 505.

The flat optical substrate 410 has a first surface 410a toward the aiming light source 402. The first surface 410 includes a first flat optical element. The first flat optical element may be a lens for collimating or focusing the aiming illumination. For example, the first flat optical element may include a metalens, a Fresnel lens, or a kinoform lens, that collimates the aiming illumination through the flat optical substrate 410.

The flat optical substrate 410 has a second surface 410b parallel to the first surface 410a and opposite the first surface 410a. The optical substrate 410 has a thickness 412 with the first and second surfaces 410a and 410b separated by a distance equal to the thickness 412 of the optical substrate 410. The second surface 410b includes a second flat optical element. The second flat optical element may be a diffractive optical element (DOE) that diffracts the aiming illumination to form an aiming pattern 520 in a FOV of an imaging reader, such as the imaging reader devices and systems of FIGS. 1-3. The DOE may include elements that are diffractive, as well as elements to further manipulate light into a pattern. For example, the DOE may also include a microlens array to generate the aiming pattern. While illustrated as a central dot and two horizontal line segments, the aiming pattern may include one or more dots, one or more line segments, a dotted line, mixed dots and dashes, geometric shapes such as circles and rectangles, or other visual patterns to identify a location or region in a FOV. Additionally, the flat optical substrate 410 may be removable from the optical assembly 400, and another flat optical substrate 410 with different first and second flat optical elements, or different diffractive patterns, may be placed in the optical assembly 400 to provide different aiming patterns.

The optical assembly 400 further includes a photodetector 502 that detects some reflected light from the optical substrate 410. The detected light provides a feedback signal to monitor the intensity of the light provided by the aiming light source 402. The photodetector 502 may provide a signal indicative of the intensity of the reflected light to a controller or processor to increase or decrease a current or voltage provided to the light source 402 to increase or decrease the output intensity of light provided by the light source 402.

FIG. 5 is a cross-sectional side view block diagram of optical elements of the optical assembly 400 of FIG. 4. The aiming light source 402 provides laser illumination 517 to the first surface 410a of the optical substrate 410. The first surface 410a includes first flat optical element 510a and a portion of aiming illumination 517a is incident on the first flat optical element 510a. As described herein, the first flat optical element 510a collimates the aiming illumination to form collimated illumination 517b that propagates along the optical axis A through the optical substrate 410. The first surface 410a further includes a reflective element 525, which may be a window or mirror. Here, a window may be an optical surface having a refractive index different than the refractive index of air in the region or environment. Therefore, the window may provide reflection of light off the window due to the difference between the refractive index of the window, and the refractive index of air. The reflective element 525 that reflects a second portion of the aiming illumination 515a as reflected illumination 515b to the photodiode 502 for monitoring the output intensity of the light source 402. The photodiode 502 is disposed to detect the reflected illumination 515b to generate a signal indicative of the reflected illumination 515b for further controlling an output of the light source 402.

The collimated illumination 517b propagates through the optical substrate 410 to the second surface 410b of the substrate 410. The second surface 410b includes a second flat optical element 510b to manipulate the collimated illumination 517b to form the aiming pattern 520 in a FOV of an imaging device. The second flat optical element 510b may by a DOE that forms the aiming pattern through diffraction of the collimated illumination 517b. In other examples, the second flat optical element may include other optical elements such as a microlens array or other element for forming the pattern.

As illustrated in FIG. 5, the optical assembly 400 may include a baffle 530 for blocking stray light from exiting the aiming system to prevent light pollution in the FOV of the imaging reader. For example, stray portions of the aiming illumination 517 may enter the optical substrate 410 through the first surface 410a at regions of the first surface outside of the first flat optical element 510a. The stray portions of light are not collimated and propagate through the optical substrate 410 at various angles relative to the optical axis A. The baffle 530 blocks radiation that does not propagate through the second flat optical element 510b to prevent light pollution and to ensure that the aiming pattern 520 is clearly visible to a user. While illustrated as being adjacent to the second surface 410b, the baffle 530 may be disposed adjacent to the first surface 410a to similarly block stray light from polluting the aiming pattern and the FOV of an imager. In examples, the first and second flat optical elements 510a and 510b may be independent elements that are part of two separate substrates. In such implementations, the first and/or second flat optical element 510a and 510b may be independently removable and replacable with another flat optical element to provide different aiming patterns and/or shapes, or to alter the focusing/collimating of the optical elements.

While described herein as manipulating the illumination to provide an aiming pattern, the second flat optical element 510b may diffract the collimated illumination 517b to form other types of patterns other than an aiming pattern. For example, the second flat optical element 510b may be a DOE that generates a point cloud, or another structured light pattern, that may be useful for performing depth analysis.

The above description of the accompanying drawing of FIG. 3 is one example of the systems and methods described herein. Alternative implementations of the examples presented include one or more additional or alternative elements, processes and/or devices. Additionally, or alternatively, one or more of the example blocks of the diagram may be combined, divided, re-arranged or omitted. Components represented by the blocks of the diagram are implemented by hardware, software, firmware, and/or any combination of hardware, software and/or firmware. In some examples, at least one of the components represented by the blocks is implemented by a logic circuit. As used herein, the term “logic circuit” is expressly defined as a physical device including at least one hardware component configured (e.g., via operation in accordance with a predetermined configuration and/or via execution of stored machine-readable instructions) to control one or more machines and/or perform operations of one or more machines. Examples of a logic circuit include one or more processors, one or more coprocessors, one or more microprocessors, one or more controllers, one or more digital signal processors (DSPs), one or more application specific integrated circuits (ASICs), one or more field programmable gate arrays (FPGAs), one or more microcontroller units (MCUs), one or more hardware accelerators, one or more special-purpose computer chips, and one or more system-on-a-chip (SoC) devices. Some example logic circuits, such as ASICs or FPGAs, are specifically configured hardware for performing operations (e.g., one or more of the operations described herein and represented by the flowcharts of this disclosure, if such are present). Some example logic circuits are hardware that executes machine-readable instructions to perform operations (e.g., one or more of the operations described herein and represented by the flowcharts of this disclosure, if such are present). Some example logic circuits include a combination of specifically configured hardware and hardware that executes machine-readable instructions. The above description refers to various operations described herein and flowcharts that may be appended hereto to illustrate the flow of those operations. Any such flowcharts are representative of example methods disclosed herein. In some examples, the methods represented by the flowcharts implement the apparatus represented by the block diagrams. Alternative implementations of example methods disclosed herein may include additional or alternative operations. Further, operations of alternative implementations of the methods disclosed herein may combined, divided, re-arranged or omitted. In some examples, the operations described herein are implemented by machine-readable instructions (e.g., software and/or firmware) stored on a medium (e.g., a tangible machine-readable medium) for execution by one or more logic circuits (e.g., processor(s)). In some examples, the operations described herein are implemented by one or more configurations of one or more specifically designed logic circuits (e.g., ASIC(s)). In some examples, the operations described herein are implemented by a combination of specifically designed logic circuit(s) and machine-readable instructions stored on a medium (e.g., a tangible machine-readable medium) for execution by logic circuit(s).

As used herein, each of the terms “tangible machine-readable medium,” “non-transitory machine-readable medium” and “machine-readable storage device” is expressly defined as a storage medium (e.g., a platter of a hard disk drive, a digital versatile disc, a compact disc, flash memory, read-only memory, random-access memory, etc.) on which machine-readable instructions (e.g., program code in the form of, for example, software and/or firmware) are stored for any suitable duration of time (e.g., permanently, for an extended period of time (e.g., while a program associated with the machine-readable instructions is executing), and/or a short period of time (e.g., while the machine-readable instructions are cached and/or during a buffering process)). Further, as used herein, each of the terms “tangible machine-readable medium,” “non-transitory machine-readable medium” and “machine-readable storage device” is expressly defined to exclude propagating signals. That is, as used in any claim of this patent, none of the terms “tangible machine-readable medium,” “non-transitory machine-readable medium,” and “machine-readable storage device” can be read to be implemented by a propagating signal.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings. Additionally, the described embodiments/examples/implementations should not be interpreted as mutually exclusive, and should instead be understood as potentially combinable if such combinations are permissive in any way. In other words, any feature disclosed in any of the aforementioned embodiments/examples/implementations may be included in any of the other aforementioned embodiments/examples/implementations.

The benefits, advantages, solutions to problems, and any element(s) that may cause any benefit, advantage, or solution to occur or become more pronounced are not to be construed as a critical, required, or essential features or elements of any or all the claims. The claimed invention is defined solely by the appended claims including any amendments made during the pendency of this application and all equivalents of those claims as issued.

Moreover, in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter may lie in less than all features of a single disclosed embodiment. Thus, the following claims are hereby incorporated into the Detailed Description, with each claim standing on its own as a separately claimed subject matter.

We claim:

1. An optical pattern generating system comprising:
a light source configured to provide light along an optical axis, the light source including a vertical-cavity surface-emitting laser; and
an optical substrate disposed along the optical axis configured to receive the light from the light source, the optical substrate having (i) a first surface having a first flat optical element thereon, the first flat optical element being an element that collimates the light, (ii) a second surface having a second flat optical element thereon, the second flat optical element configured to diffract the light to form an optical pattern, and (iii) a thickness defined by the distance between the first surface and second surface.

2. The system of claim 1, wherein the first flat optical element comprises a metalens, Fresnel lens, or kinoform lens.

3. The system of claim 1, wherein the second flat optical element comprises a flat diffractive optical element.

4. The system of claim 3, wherein the diffractive optical element diffracts the light to form an optical aiming pattern.

5. The system of claim 3, wherein the diffractive optical element diffracts the light to form a point cloud pattern.

6. The system of claim 1, further comprising a photodiode disposed to detect a portion of the light and configured to generate a signal indicative of the detected portion of the light.

7. The system of claim 6, wherein the first surface further comprises a reflective element on the first surface, the reflective element configured to reflect the portion of the radiation from the first surface to the photodiode.

8. The system of claim 7, where the reflective element comprises a mirror.

9. The system of claim 1, further comprising an optical baffle disposed along the optical axis configured to (i) transmit the manipulated light from the second flat optical element, and (ii) block stray light from exiting the system.

10. The system of claim 1, further comprising a printed circuit board having the light source disposed thereon, the light source being electrically coupled to the printed circuit board.

11. The system of claim 10, wherein the light source comprises a surface mount device and the light source is surface mounted to the printed circuit board.

12. The system of claim 1, further comprising:
a lead frame having mount solder pads, wherein the light source is physically and electrically coupled to the lead frame;
a photodiode physically and electrically coupled to the lead frame; and
a printed circuit board with the lead frame physically and electrically coupled to the printed circuit board.

13. The system of claim 1, wherein the second flat optical element has a diffraction pattern, and wherein the second flat optical element is removable from the optical substrate and replaceable with another flat optical element having a different diffractive pattern.

14. An optical pattern generating system comprising:
a housing structure having (i) one or more side walls, (ii) a bottom wall, and (iii) a front aperture disposed along an optical axis, the front aperture configured to allow light to propagate through the front aperture;
a printed circuit board disposed in the housing structure and supported in position by the housing structure;
a light source physically and electrically coupled to the printed circuit board, the light source being a vertical-cavity surface-emitting laser configured to provide light along the optical axis;
an optical substrate disposed in the housing, the optical substrate having (i) a first surface toward the light source, the first surface having a first flat optical element thereon the first flat optical element configured to collimate the light, (ii) a second surface opposite the first surface, the second surface having a second flat optical element thereon the second flat optical element configured to diffract the light into an optical pattern, and (ii) a thickness defined by the distance from the first surface to the second surface.

15. The system of claim 14, further comprising a baffle disposed on the front aperture configure to block light from exiting a portion of the front aperture.

16. The system of claim 14, wherein the housing has a width of less than 3 millimeters between opposite walls of the one or more side walls, and a height of less than 3 millimeters between the bottom wall and the front aperture.
